(19) United States
(12) Patent Application Publication
(10) Pub. No.: US 2025/0298693 A1
(43) Pub. Date: Sep. 25, 2025

(54) ERROR CORRECTION CODE CIRCUIT, MEMORY SYSTEM INCLUDING THE SAME, AND METHOD OF ERROR CORRECTION FOR MEMORY DEVICE

(71) Applicant: SAMSUNG ELECTRONICS CO., LTD., Suwon-si (KR)

(72) Inventors: Yeonho JUNG, Suwon-si (KR); Dohui KIM, Suwon-si (KR); Soohoh SEOL, Suwon-si (KR); Gyuseong KANG, Suwon-si (KR); Mijoung KIM, Suwon-si (KR); Dohoon BYUN, Suwon-si (KR); Hyun-Jin SHIN, Suwon-si (KR); Kunhoe CHA, Suwon-si (KR)

(73) Assignee: SAMSUNG ELECTRONICS CO., LTD., Suwon-si (KR)

(21) Appl. No.: 18/970,334

(22) Filed: Dec. 5, 2024

(30) Foreign Application Priority Data
Mar. 19, 2024 (KR) 10-2024-0038085

(51) Int. Cl. G06F 11/10

(52) U.S. Cl. CPC G06F 11/1068; G06F 11/1016

(57) ABSTRACT

Disclosed is an ECC circuit, which includes a first sub-ECC circuit to correct a first error including first error bits; a second sub-ECC circuit to correct a second error including second error bits; an output multiplexer circuit to output a plurality of bits, wherein a first plurality of bits among the plurality of bits is output to the first sub-ECC circuit, and wherein a second plurality of bits among the plurality of bits is output to the second sub-ECC circuit; and a control logic circuit configured to control the output multiplexer circuit, and wherein the control logic circuit is further configured to: control the output multiplexer circuit to output at least one of the first error bits to the second sub-ECC circuit based on a number of the first error bits exceeding a first number and a number of the second error bits is less than the first number.

### CROSS-REFERENCE TO RELATED APPLICATIONS

This application claims priority under 35 U.S.C. § 119 to Korean Patent Application No. 10-2024-0038085 filed on Mar. 19, 2024, in the Korean Intellectual Property Office, the disclosures of which are incorporated by reference herein in their entireties.

### BACKGROUND

Embodiments of the present disclosure described herein relate to an error correction code circuit, a memory system including the same, and a method of an error correction for a memory device.

Nonvolatile memories are a type of computer memory that may retain stored information even when the power supply is interrupted. A flash memory is an example of a nonvolatile memory. Along with a flash memory, resistive memories such as a PRAM (Phase change RAM), a NFGM (Nano Floating Gate Memory), a PoRAM (Polymer RAM), an MRAM (Magnetic RAM), an FeRAM (Ferroelectric RAM), and an RRAM (Resistive RAM) are known as nonvolatile memory devices.

A nonvolatile memory system generally includes a memory controller and a nonvolatile memory (NVM) device.

The nonvolatile memory system may include an error correction code (ECC) circuit that corrects data to be written to the NVM device or data read from the NVM device.

In particular, in the case of an MRAM, which stores or reads data depending on the magnetization direction and the resistance value formed by the current applied to a variable resistance element, error bits may occur during the process of storing and reading data due to the characteristics of using quantum mechanical effects. Therefore, in the case of memory systems that utilize the quantum mechanical effects, such as the MRAM, ECC circuits are essentially provided.

However, to increase the number of error bits that the ECC circuit may correct, a circuit configuration for implementing the memory system may increase exponentially.

### SUMMARY

Embodiments of the present disclosure provide an ECC circuit that improves an operation speed of a memory system and the number of bits capable of error correction.

According to an embodiment of the present disclosure, an ECC circuit includes a first sub-ECC circuit configured to correct a first error which includes first error bits; a second sub-ECC circuit configured to correct a second error which includes second error bits; an output multiplexer circuit configured to output a plurality of bits, wherein a first plurality of bits among the plurality of bits is output to the first sub-ECC circuit, and wherein a second plurality of bits among the plurality of bits is output to the second sub-ECC circuit; and a control logic circuit configured to control the output multiplexer circuit, and wherein the control logic circuit is further configured to: control the output multiplexer circuit to output at least one of the first error bits to the second sub-ECC circuit based on a number of the first error bits exceeding a first number and a number of the second error bits is less than the first number.

According to an embodiment of the present disclosure, a method of performing an error correction for a plurality of bits read from a memory device includes storing a plurality of input bits in the memory device; reading a plurality of bits stored at an address corresponding to an address value of the plurality of input bits from the memory device; determining a number of first error bits occurring in a first plurality of bits among the plurality of bits in which a first sub-ECC circuit is error-correctable, and a number of second error bits occurring in a second plurality of bits among the plurality of bits in which a second sub-ECC circuit is error-correctable; and controlling an output multiplexer circuit to output at least one of the first error bits to the second sub-ECC circuit based on the number of the first error bits exceeding a first number and the number of the second error bits being less than the first number.

According to an embodiment of the present disclosure, a memory system includes a memory device that reads a plurality of bits, and a memory controller that controls an operation of the memory device, and the memory controller includes an ECC circuit including a first sub-ECC circuit configured to correct a first error comprising first error bits, and a second sub-ECC circuit configured to correct a second error comprising second error bits, and wherein the memory device comprises: an output multiplexer circuit configured to output the plurality of bits, wherein a first plurality of bits among the plurality of bits is output to the first sub-ECC circuit, and wherein a second plurality of bits among the plurality of bits is output to the second sub-ECC circuit; and a control logic circuit configured to control the output multiplexer circuit, and wherein the control logic circuit is further configured to: control the output multiplexer circuit to output at least some of the first error bits to the second sub-ECC circuit based on a number of the first error bits exceeding a first number and a number of the second error bits being less than the first number.

### BRIEF DESCRIPTION OF DRAWINGS

The above and other objects and features of the present disclosure will become apparent by describing in detail embodiments thereof with reference to the accompanying drawings.

FIG. 1A is a block diagram illustrating a memory system, according to an embodiment of the present disclosure.

FIG. 1B is a diagram illustrating a memory system which an ECC circuit receives a plurality of bits read from a memory device, according to an embodiment of the present disclosure.

FIG. 2 is a block diagram illustrating an output multiplexer circuit including a plurality of multiplexers outputs a plurality of bits to a Sub-ECC circuit, according to an embodiment.

FIG. 3 is a block diagram illustrating a control logic controlling an output multiplexer circuit, according to an embodiment.

FIG. 4A is a block diagram illustrating a control logic controlling an output multiplexer circuit, according to an embodiment.

FIG. 4B is a block diagram illustrating a control logic controlling an output multiplexer circuit, according to an embodiment.

FIG. 5 is a block diagram illustrating a control logic controlling an output multiplexer circuit, according to an embodiment.

FIG. 6 is a block diagram illustrating a control logic controlling an output multiplexer circuit, according to an embodiment.

FIG. 7 is a flowchart illustrating an error correction process for a memory device, according to an embodiment.

FIG. 8 is a flowchart illustrating a process of controlling multiplexers included in an output multiplexer circuit, according to an embodiment.

FIG. 9 is a flowchart illustrating a process of storing selection information and address information according to values of a plurality of bits, according to an embodiment.

FIG. 10 is a flowchart illustrating a process of controlling an output multiplexer circuit based on stored address information and stored selection information, according to an embodiment.

FIG. 11 is a block diagram illustrating a memory system, according to an embodiment.

FIG. 12 is a block diagram illustrating a memory system in which a control logic circuit controls an input multiplexer and an output multiplexer, according to an embodiment.

FIG. 13 is a block diagram illustrating a memory system including a memory controller and a memory device, according to an embodiment.

FIG. 14 is a block diagram illustrating a memory device in FIG. 13.

### DETAILED DESCRIPTION

Hereinafter, embodiments of the present disclosure will be described clearly and in detail such that those skilled in the art may easily carry out the technical idea of the present disclosure.

Expressions such as “first”, “second”, or the like used in the present disclosure may modify various elements regardless of order and/or importance, and are used only to distinguish one element from another element and do not limit the order or the importance of the elements.

As is traditional in the field of the disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

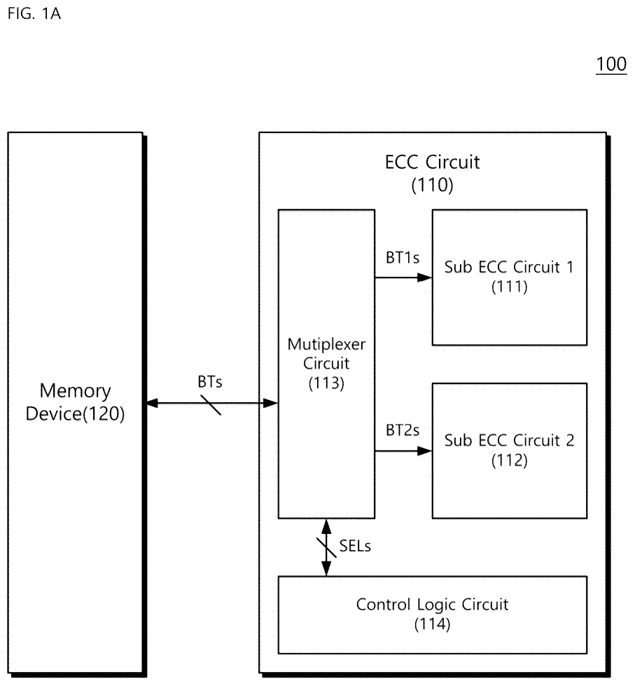

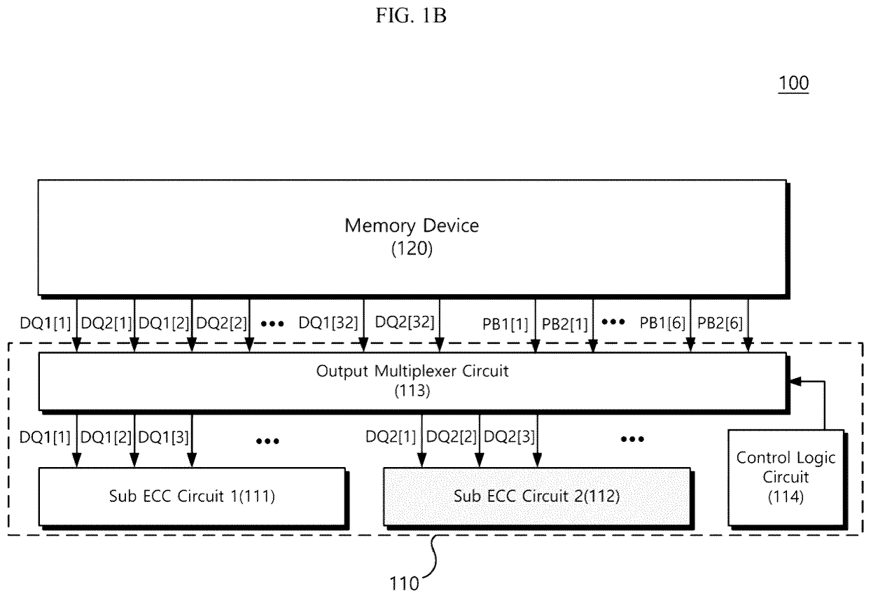

FIG. 1A is a block diagram illustrating a memory system, according to an embodiment of the present disclosure. FIG. 1B illustrates a configuration in which an ECC circuit of FIG. 1A receives a plurality of bits read from a memory device.

As shown in FIGS. 1A and 1B together, a memory system 100 according to an embodiment may include an error correction code (ECC) circuit 110 and a memory device 120.

The memory system 100 may include the memory device 120 that stores input data.

In more detail, the memory device 120 may store data input from the outside. In addition, the memory device 120 may output stored data in response to a read request received from the outside.

In this case, the memory device 120 may be a nonvolatile memory such as a flash memory, a magnetic RAM (MRAM), a ferroelectric RAM (FeRAM), a phase change RAM (PRAM), and a resistive RAM (ReRAM). However, the embodiments of the present disclosure are not limited thereto, and as an example, the memory device 120 may include a dynamic random access memory (DRAM), such as a Double Data Rate Synchronous Dynamic Random Access Memory (DDR SDRAM), a Low Power Double Data Rate (LPDDR) SDRAM, a Graphics DDR (GDDR), etc.

However, below, for convenience of description, it is assumed that the memory device 120 is an MRAM.

In addition, the memory system 100 may include the ECC circuit 110 connected to the memory device 120.

According to an embodiment, the ECC circuit 110 may receive a plurality of bits BTs output from the memory device 120. In addition, the ECC circuit 110 may transmit the plurality of bits BTs to the memory device 120.

According to an embodiment, the ECC circuit 110 may correct bits (hereinafter referred to as “error bits”) being erroneous from among the plurality of bits BTs output from the memory device 120 to be output.

In more detail, the ECC circuit 110 may correct error bits that have a different value from the bits input to the memory device 120 among the plurality of bits BTs output from the memory device 120 to be output.

According to an embodiment, the ECC circuit 110 may include a first sub-ECC circuit 111, a second sub-ECC circuit 112, an output multiplexer circuit 113 (referred to as “multiplexer circuit 113” in FIG. 1A), and a control logic circuit 114.

The ECC circuit 110 may include the first sub-ECC circuit 111 and the second sub-ECC circuit 112, which correct the error which includes error bits, the number of which is less than a first number, respectively. As an example, the first sub-ECC circuit 111 may correct first error bits and the second sub-ECC circuit 112 may correct second error bits. A number of the first error bits and a number of the second error bits may be less than or equal to the first number.

In more detail, the ECC circuit 110 may include the first sub-ECC circuit 111 that corrects the error of error bits, the number of which is less than or equal to the first number, among a plurality of first bits BT1s.

As shown in FIG. 1B, the plurality of first bits BT1s (may also be referred to as “first plurality of bits”) may include a plurality of first data bits DQ1[1] to DQ1[32] and a plurality of first parity bits PB1[1] to PB1[6].

Therefore, for example, the first sub-ECC circuit 111 may correct the error which includes first error bits, the number of which is less than or equal to the first number, among the plurality of first data bits DQ1[1] to DQ1[32] by using at least some of the plurality of first parity bits PB1[1] to PB1[6].

For another example, the first sub-ECC circuit 111 may correct the error which includes error bits, the number of which is less than or equal to the first number, among the plurality of first parity bits PB1[1] to PB1[6] by using at least some of the plurality of first parity bits PB1[1] to PB1[6].

In addition, for example, the first sub-ECC circuit 111 may correct the error which includes first error bits, the number of which is two or less, among 32 first data bits DQ1[1] to DQ1[32] input from the output multiplexer circuit 113.

In addition, the ECC circuit 110 may include the second sub-ECC circuit 112 that corrects the error which includes error bits, the number of which is less than or equal to the first number, among a plurality of second bits BT2s.

As shown in FIG. 1B, the plurality of second bits BT2s (may also be referred to as “second plurality of bits”) may include a plurality of second data bits DQ2[1] to DQ2[32] and a plurality of second parity bits PB2[1] to PB2[6].

Therefore, for example, the second sub-ECC circuit 112 may correct the error which includes second error bits, the number of which is less than or equal to the first number, among the plurality of second data bits DQ2[1] to DQ2[32] by using at least some of the plurality of second parity bits PB2[1] to PB2[6].

For another example, the second sub-ECC circuit 112 may correct the error which includes error bits, the number of which is less than or equal to the first number, among the plurality of second parity bits PB2[1] to PB2[6] by using at least some of the plurality of second parity bits PB2[1] to PB2[6].

In addition, for example, the second sub-ECC circuit 112 may correct the error which includes second error bits, the number of which is two or less, among 32 second data bits DQ2[1] to DQ2[32] input from the output multiplexer circuit 113.

In detail, the ECC circuit 110 may correct the error which includes error bits, the number of which is less than or equal to a second number (e.g., 4) which is twice the first number (e.g., 2), among the plurality of bits BTs.

However, the number and the configuration of the plurality of bits BTs, the plurality of first bits BT1s, and the plurality of second bits BT2s are not limited to the above-described examples.

As shown in FIG. 1A, the ECC circuit 110 may include the output multiplexer circuit 113 that outputs the plurality of first bits BT1s among the plurality of bits BTs output from the memory device 120 to the first sub-ECC circuit 111 and outputs the plurality of second bits BT2s to the second sub-ECC circuit 112.

For example, as shown in FIG. 1B, the output multiplexer circuit 113 may output the 32 first data bits DQ1[1] to DQ1[32] and/or the 6 first parity bits PB1[1] to PB1[6]) among the plurality of bits BTs to the first sub-ECC circuit 111.

In addition, for example, the output multiplexer circuit 113 may output the 32 second data bits DQ2[1] to DQ2[32] and/or the 6 second parity bits PB2[1] to PB2[6] among the plurality of bits BTs to the second sub-ECC circuit 112.

In addition, the ECC circuit 110 may include the control logic circuit 114 that controls the output multiplexer circuit 113.

The control logic circuit 114, for example, may execute software (or program) to control at least one other component (e.g., the output multiplexer circuit 113) of the ECC circuit 110, and may perform various data processing or calculations. The control logic circuit 114 may include a central processing unit or a microprocessor, and may control the overall operation of the ECC circuit 110. Accordingly, the operation performed by the ECC circuit 110 may be understood as being performed under the control of the control logic circuit 114.

According to an embodiment, the control logic circuit 114 may include an algorithm for controlling the output multiplexer circuit 113. For example, the algorithm may be software code programmed inside the control logic circuit 114. As another example, the algorithm may be hard codes obtained by hard coding inside the control logic circuit 114, but is not limited thereto.

In more detail, the control logic circuit 114 may control the output multiplexer circuit 113 by outputting a plurality of selection signals SELs depending on an algorithm.

According to an embodiment, the control logic circuit 114 may control the output multiplexer circuit 113 to output at least some of the plurality of first bits BT1s to the first sub-ECC circuit 111.

In addition, the control logic circuit 114 may control the output multiplexer circuit 113 to output at least some of the plurality of second bits BT2s to the second sub-ECC circuit 112.

In addition, the control logic circuit 114 may determine the number of error bits that occur in each of the plurality of first bits BT1s and the plurality of second bits BT2s.

For example, the control logic circuit 114 may determine the number of first error bits in which an error occurs among the plurality of first bits BT1s. In addition, the control logic circuit 114 may determine the number of second error bits in which an error occurs among the plurality of second bits BT2s.

Furthermore, the control logic circuit 114 may control the output multiplexer circuit 113 to output at least some of the first error bits to the second sub-ECC circuit 112 when the number of first error bits exceeds the first number.

For example, the control logic circuit 114 may control the output multiplexer circuit 113 to output at least some of the first error bits to the second sub-ECC circuit 112 when the first error bits exceeding the first number among the plurality of first bits BT1s occur, and when the second error bits less than the first number among the plurality of second bits BT2s occur.

According to another embodiment, when the number of second error bits exceeds the first number, the control logic circuit 114 may control the output multiplexer circuit 113 to output at least some of the plurality of second bits BT2s to the first sub-ECC circuit 111.

For example, the control logic circuit 114 may control the output multiplexer circuit 113 to output at least some of the second error bits to the first sub-ECC circuit 111 when the second error bits exceeding the first number among the plurality of second bits BT2s occur, and when the first error bits, the number of which is less than the first number, among the plurality of first bits BT1s occur.

When there occur error bits, the number of which is less than or equal to the second number, the control logic circuit 114 may control the output multiplexer circuit 113 such that each of the first sub-ECC circuit 111 and the second sub-ECC circuit 112 receives error bits, the number of which is less than or equal to the first number, to correct the error.

According to embodiments in the present disclosure, the ECC circuit 110 according to an embodiment may utilize two sub-ECC circuits 111 and 112, each correcting error bits, the number of which is less than or equal to the first number, to correct the error in the second number of error bits which is twice the first number.

In detail, the ECC circuit 110 may correct the error which includes error bits exceeding a specified number by utilizing the plurality of sub-ECC circuits 111 and 112, each of which corrects error bits, the number of which is less than or equal to the specified number.

The ECC circuit 110 may correct a relatively large number of error bits through a relatively small circuit configuration and a relatively small logic depth.

Accordingly, the ECC circuit 110 according to an embodiment of the present disclosure may improve the operation speed of the memory system 100 by using a relatively small circuit configuration and a relatively small logic depth.

In addition, the ECC circuit 110 may include the plurality of sub-ECC circuits 111 and 112 that correct error bits, the number of which is less than or equal to a specified number, among different bits, thereby increasing the number of bits capable of error correction in the memory system 100.

Accordingly, the ECC circuit 110 according to an embodiment of the present disclosure may improve the operation speed of the memory device 120 (or the memory system 100) by having a relatively small circuit configuration.

In addition, the ECC circuit 110 may improve the yield of the memory device 120 (or the memory system 100) by increasing the number of bits capable of error correction.

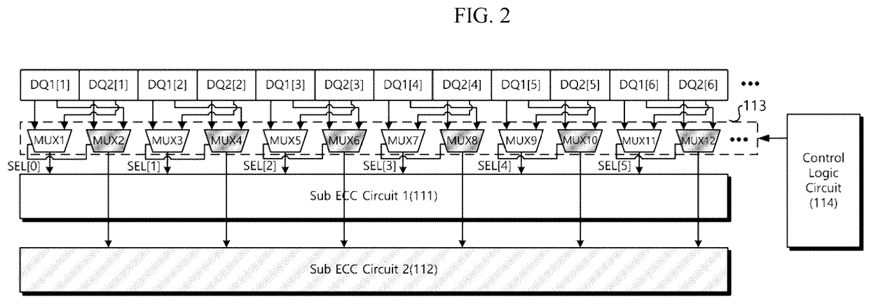

FIG. 2 illustrates a configuration in which an output multiplexer circuit including a plurality of multiplexers outputs a plurality of bits to a first sub-ECC circuit or a second sub-ECC circuit, according to an embodiment.

As shown in FIG. 2, the output multiplexer circuit 113 according to an embodiment may include a plurality of output multiplexers MUX1 to MUX12.

In more detail, the output multiplexer circuit 113 may include the plurality of output multiplexers MUX1 to MUX12 connected to one bit of the plurality of first bits BT1s and one bit of the plurality of second bits BT2s, respectively.

The number of multiplexers included in the output multiplexer circuit 113 according to the present disclosure is not limited to the above description, and may be understood as having a number corresponding to the number of plurality of bits BTs.

However, in the drawings and the description below, for convenience of description, the output multiplexer circuit 113 will be indicated and described as including the first to twelfth output multiplexers MUX1 to MUX12.

In addition, the control logic circuit 114 may control at least some of the plurality of output multiplexers MUX1 to MUX12 to provide each of the plurality of bits BTs to the first sub-ECC circuit 111 or the second sub-ECC circuit 112.

For example, the output multiplexer circuit 113 may include the first output multiplexer MUX1 connected to the 1-1 bit DQ1[1] and the 2-1 bit DQ2[1].

In this case, the first output multiplexer MUX1 may selectively output one of the 1-1 bit DQ1[1] and the 2-1 bit DQ2[1] to the first sub-ECC circuit 111 based on a first selection signal SEL[0].

For example, the output multiplexer circuit 113 may include the second output multiplexer MUX2 connected to the 1-1 bit DQ1[1] and the 2-1 bit DQ2[1].

In this case, the second output multiplexer MUX2 may selectively output one of the 1-1 bit DQ1[1] and the 2-1 bit DQ2[1] to the second sub-ECC circuit 112 based on the first selection signal SEL[0].

In detail, the first output multiplexer MUX1 and the second output multiplexer MUX2 may output different bits of the 1-1 bit DQ1[1] and the 2-1 bit DQ2[1] to the first sub-ECC circuit 111 and the second sub-ECC circuit 112, respectively, based on the first selection signal SEL[0].

In this case, for example, the first output multiplexer MUX1 and the second output multiplexer MUX2 may be understood as forming a pair.

In addition, for example, the output multiplexer circuit 113 may include the third output multiplexer MUX3 connected to the 1-2 bit DQ1[2] and the 2-2 bit DQ2[2].

In this case, the third output multiplexer MUX3 may selectively output one of the 1-2 bit DQ1[2] and the 2-2 bit DQ2[2] to the first sub-ECC circuit 111 based on a second selection signal SEL[1].

In addition, for example, the output multiplexer circuit 113 may include the fourth output multiplexer MUX4 connected to the 1-2 bit DQ1[2] and the 2-2 bit DQ2[2].

In this case, the fourth output multiplexer MUX4 may selectively output one of the 1-2 bit DQ1[2] and the 2-2 bit DQ2[2] to the second sub-ECC circuit 112 based on the second selection signal SEL[1].

In detail, the third output multiplexer MUX3 and the fourth output multiplexer MUX4 may output different bits of the 1-2 bit DQ1[2] and the 2-2 bit DQ2[2] to the first sub-ECC circuit 111 and the second sub-ECC circuit 112, respectively, based on the second selection signal SEL[1].

Accordingly, the third output multiplexer MUX3 and the fourth output multiplexer MUX4 may be understood as forming a pair.

Accordingly, the output multiplexer circuit 113 may include the plurality of output multiplexers MUX1 to MUX12 that operate in pairs.

In addition, the control logic circuit 114 may control at least some of the plurality of output multiplexers MUX1 to MUX12 included in the output multiplexer circuit 113 such that each of the first sub-ECC circuit 111 and the second sub-ECC circuit 112 receives and corrects error bits less than or equal to the first number.

According to embodiments of the present disclosure, the ECC circuit 110 according to an embodiment may control at least some of the plurality of output multiplexers MUX1 to MUX12 to correct a relatively large number of error bits using a relatively small circuit configuration.

Accordingly, the ECC circuit 110 according to an embodiment of the present disclosure may improve the operation speed of the memory system 100 by using a relatively small circuit configuration.

In addition, the ECC circuit 110 may include the plurality of sub-ECC circuits 111 and 112 that correct error bits, the number of which is less than or equal to a specified number, among distinct bits, thereby increasing the number of bits capable of error correction in the memory system 100.

Through this, the ECC circuit 110 may improve the performance (e.g., a read speed) and the yield of the memory device 120 (or the memory system 100).

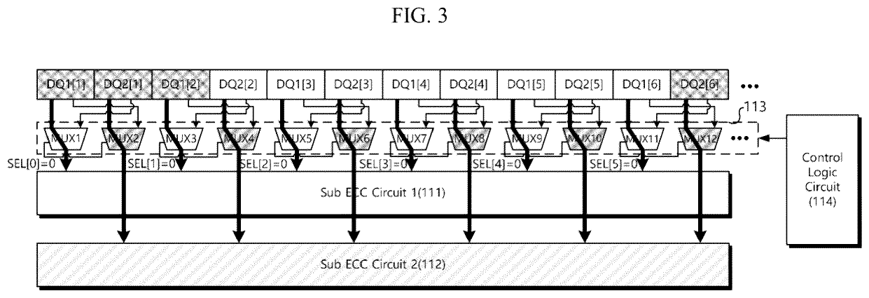

FIG. 3 illustrates a configuration in which a control logic circuit controls an output multiplexer circuit when each of the number of first error bits and the number of second error bits is less than a first number, according to an embodiment.

As shown in FIG. 3, the control logic circuit 114 according to an embodiment may control the output multiplexer circuit 113 to output each of the plurality of bits BTs to the first sub-ECC circuit 111 and the second sub-ECC circuit 112.

In more detail, when error bits, the number of which is less than or equal to the first number, occur in each of the plurality of first bits BT1s and the plurality of second bits BT2s, the control logic circuit 114 may control the output multiplexer circuit 113 to output each of the plurality of first bits BT1s and the plurality of second bits BT2s to the first sub-ECC circuit 111 and the second sub-ECC circuit 112.

For example, when error bits, the number of which is less than or equal to the first number, occur in each of the plurality of first bits BT1s and the plurality of second bits BT2s, the control logic circuit 114 may input a selection signal with a value of “0” to each of the plurality of output multiplexers MUX1 to MUX12.

Through this, the control logic circuit 114 may control the output multiplexer circuit 113 to output the plurality of first bits BT1s and the plurality of second bits BT2s to the first sub-ECC circuit 111 and the second sub-ECC circuit 112, respectively.

In this case, it is assumed that each of the first sub-ECC circuit 111 and the second sub-ECC circuit 112 may correct the error which includes error bits, the number of which is less than or equal to the first number (e.g., ‘2’).

When first error bits, the number of which is less than or equal to the first number, among the plurality of first bits BT1s occur, the control logic circuit 114 may control the output multiplexer circuit 113 to output the plurality of first bits BT1s to the first sub-ECC circuit 111.

For example, when an error occurs in two bits DQ1[1] and DQ1[2] among the plurality of first bits BT1s, the control logic circuit 114 may control the output multiplexer circuit 113 to output the plurality of first bits BT1s including the 1-1 bit DQ1[1]) and the 1-2 bit DQ1[2] to the first sub-ECC circuit 111.

When second error bits, the number of which is less than or equal to the first number, among the plurality of second bits BT2s occur, the control logic circuit 114 may control the output multiplexer circuit 113 to output the plurality of second bits BT2s to the second sub-ECC circuit 112.

For example, when an error occurs in two bits DQ2[1] and DQ2[6] among the plurality of second bits BT2s, the control logic circuit 114 may control the output multiplexer circuit 113 to output the plurality of second bits BT2s including the 2-1 bit DQ2[1] and the 2-6 bit DQ2[6] to the second sub-ECC circuit 112.

Furthermore, each of the first sub-ECC circuit 111 and the second sub-ECC circuit 112 may correct the error which includes input error bits, the number of which is less than or equal to the first number.

In more detail, the first sub-ECC circuit 111 may correct the 1-1 bit DQ1[1] and the 1-2 bit DQ1[2] in which an error occurs among the plurality of input first bits BT1s.

In addition, the second sub-ECC circuit 112 may correct the 2-1 bit DQ2[1] and the 2-6 bit DQ2[6] in which an error occurs among the plurality of input second bits BT2s.

According to embodiments of the present disclosure, when error bits occur, the number of which is less than or equal to the second number, among the plurality of bits BTs, the control logic circuit 114 may control the output multiplexer circuit 113 such that each of the first sub-ECC circuit 111 and the second sub-ECC circuit 112 receives and corrects error bits, the number of which is less than or equal to the first number.

In detail, the ECC circuit 110 may correct a relatively large number of error bits through a relatively small circuit configuration.

Through this, the ECC circuit 110 may improve the performance (e.g., the read speed) and the yield of the memory device 120 (or the memory system 100).

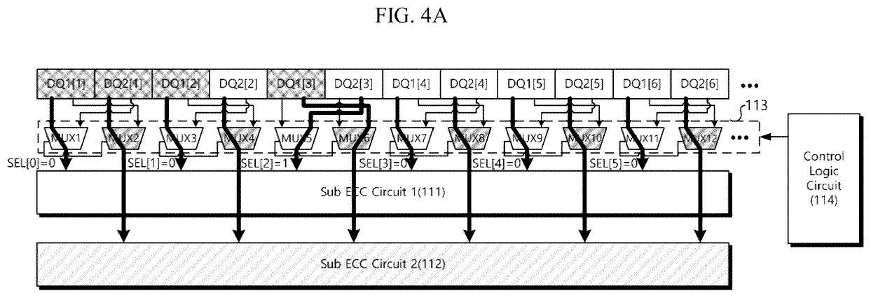

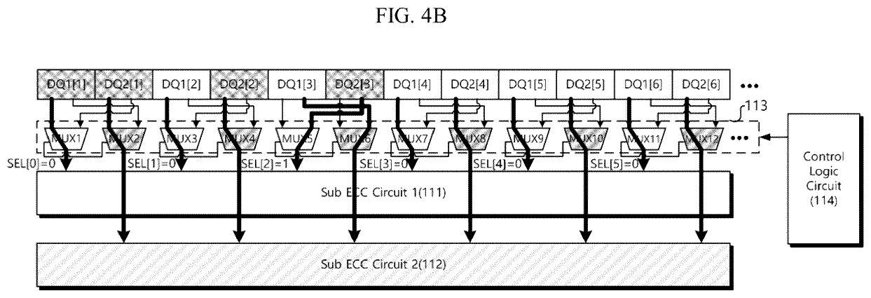

FIG. 4A illustrates a configuration in which a control logic circuit controls an output multiplexer circuit when the number of first error bits exceeds a first number and the number of second error bits is less than a first number, according to an embodiment. FIG. 4B illustrates a configuration in which a control logic circuit controls an output multiplexer circuit when the number of first error bits is less than a first number and the number of second error bits exceeds a first number, according to an embodiment.

As shown in FIG. 4A, when first error bits exceeding the first number occur in the plurality of first bits BT1s, the control logic circuit 114 according to an embodiment may control the output multiplexer circuit 113 to output at least one of the first error bits to the second sub-ECC circuit 112.

In more detail, when first error bits exceeding the first number occur in the plurality of first bits BT1s, and second error bits, the number of which is less than the first number, occur in the plurality of second bits BT2s, the control logic circuit 114 may control the output multiplexer circuit 113 to output at least some of the first error bits to the second sub-ECC circuit 112.

In this case, it is assumed that each of the first sub-ECC circuit 111 and the second sub-ECC circuit 112 may correct the error which includes error bits, the number of which is less than or equal to the first number (e.g., ‘2’).

According to an embodiment, when three first error bits (e.g., DQ1[1], DQ1[2], and DQ1[3]) occur in the plurality of first bits BT1s, and one second error bit (e.g., DQ2[1]) occurs in the plurality of second bits BT2s, the control logic circuit 114 may control the output multiplexer circuit 113 to output the 1-3 bit DQ1[3] to the second sub-ECC circuit 112.

For example, when three first error bits (e.g., DQ1[1], DQ1[2], and DQ1[3]) occur in the plurality of first bits BT1s, and one second error bit (e.g., DQ2[1]) occurs in the plurality of second bits BT2s, the control logic circuit 114 may input a third selection signal SEL[2] with a value of “1” to the fifth output multiplexer MUX5 and the sixth output multiplexer MUX6.

Through this, the control logic circuit 114 may control the fifth output multiplexer MUX5 to output a 2-3 bit DQ2[3] to the first sub-ECC circuit 111. In addition, the control logic circuit 114 may control the sixth output multiplexer MUX6 to output the 1-3 bit DQ1[3] in which an error occurs to the second sub-ECC circuit 112.

In addition, the control logic circuit 114 may input selection signals having a value of “0”, excluding the third selection signal SEL[2], to the plurality of output multiplexers MUX1, MUX2, MUX3, MUX4, and MUX7 to MUX12.

Through this, the control logic circuit 114 may control the plurality of first bits BT1s excluding the 1-3 bit DQ1[3] to be input to the first sub-ECC circuit 111. In addition, the control logic circuit 114 may control the plurality of second bits BT2s excluding the 2-3 bit DQ2[3] to be input to the second sub-ECC circuit 112.

Furthermore, each of the first sub-ECC circuit 111 and the second sub-ECC circuit 112 may correct the error which includes input error bits, the number of which is less than or equal to the first number.

For example, the first sub-ECC circuit 111 may correct the 1-1 bit DQ1[1] and the 1-2 bit DQ1[2] in which an error occurs among the input bits.

In addition, the second sub-ECC circuit 112 may correct the 2-1 bit DQ2[1] and the 1-3 bit DQ1[3] in which an error occurs among the input bits.

As shown in FIG. 4B according to another embodiment, when second error bits exceeding the first number occur in the plurality of second bits BT2s, the control logic circuit 114 may control the output multiplexer circuit 113 to output at least some of the second error bits to the first sub-ECC circuit 111.

In more detail, when second error bits exceeding the first number occur in the plurality of second bits BT2s, and first error bits, the number of which is less than the first number, occur in the plurality of first bits BT1s, the control logic circuit 114 may control the output multiplexer circuit 113 to output at least some of the second error bits to the first sub-ECC circuit 111.

In this case, it is assumed that each of the first sub-ECC circuit 111 and the second sub-ECC circuit 112 may correct the error which includes error bits, the number of which is less than or equal to the first number (e.g., ‘2’).

According to an embodiment, when one first error bit (e.g., DQ1[1]) occurs in the plurality of first bits BT1s, and three second error bits (e.g., DQ2[1], DQ2[2], and DQ2[3]) occur in the plurality of second bits BT2s, the control logic circuit 114 may control the output multiplexer circuit 113 to output the 2-3 bit DQ2[3] to the first sub-ECC circuit 111.

For example, when one first error bit (e.g., DQ1[1]) occurs in the plurality of first bits BT1s, and three second error bits (e.g., DQ2[1], DQ2[2], DQ2[3]) occur in the plurality of second bits BT2s, the control logic circuit 114 may input the third selection signal SEL[2] with a value of “1” to the fifth output multiplexer MUX5 and the sixth output multiplexer MUX6.

Through this, the control logic circuit 114 may control the fifth output multiplexer MUX5 to output the 2-3 bit DQ2[3] in which an error occurs to the first sub-ECC circuit 111. In addition, the control logic circuit 114 may control the sixth output multiplexer MUX6 to output the 1-3 bit DQ1[3] to the second sub-ECC circuit 112.

In addition, the control logic circuit 114 may input selection signals having a value of “0”, excluding the third selection signal SEL[2], to the plurality of output multiplexers MUX1, MUX2, MUX3, MUX4, and MUX7 to MUX12.

Through this, the control logic circuit 114 may control the plurality of first bits BT1s excluding the 1-3 bit DQ1[3] to be input to the first sub-ECC circuit 111. In addition, the control logic circuit 114 may control the plurality of second bits BT2s excluding the 2-3 bit DQ2[3] to be input to the second sub-ECC circuit 112.

Furthermore, each of the first sub-ECC circuit 111 and the second sub-ECC circuit 112 may correct the error which includes input error bits, the number of which is less than or equal to the first number.

For example, the first sub-ECC circuit 111 may correct the 1-1 bit DQ1[1] and the 2-3 bit DQ2[3] in which an error occurs among the input bits.

In addition, the second sub-ECC circuit 112 may correct the 2-1 bit DQ2[1] and the 2-2 bit DQ2[2] in which an error occurs among the input bits.

According to embodiments of the present disclosure, when error bits occur, the number of which is less than or equal to the second number (e.g., ‘4’), among the plurality of bits BTs, the control logic circuit 114 may control the output multiplexer circuit 113 such that each of the first sub-ECC circuit 111 and the second sub-ECC circuit 112 receives error bits, the number of which is less than or equal to the first number (e.g., ‘2’), to correct the error.

Through this, the ECC circuit 110 may correct a relatively large number of error bits through a relatively small circuit configuration and a relatively small logic depth.

Therefore, the ECC circuit 110 according to an embodiment of the present disclosure may improve the performance (e.g., a read speed) and the yield of the memory device 120 (or the memory system 100).

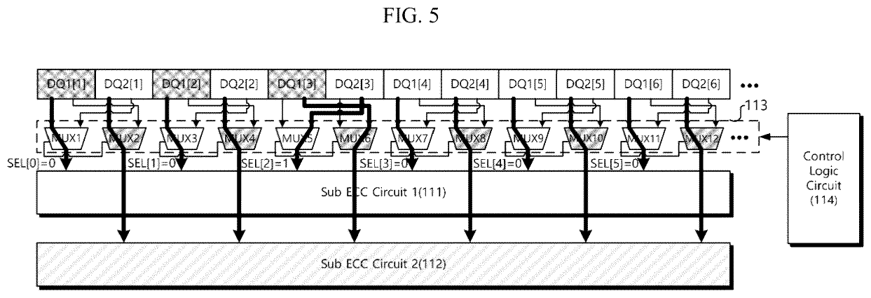

FIG. 5 illustrates a configuration in which a control logic circuit controls an output multiplexer circuit when the number of first error bits exceeds a first number, according to an embodiment.

As shown in FIG. 5, when first error bits exceeding the first number occur in the plurality of first bits BT1s, the control logic circuit 114 according to an embodiment may control the output multiplexer circuit 113 to output at least some of the first error bits to the second sub-ECC circuit 112.

In this case, it is assumed that each of the first sub-ECC circuit 111 and the second sub-ECC circuit 112 may correct the error which includes error bits, the number of which is less than or equal to the first number (e.g., ‘2’).

According to an embodiment, when three first error bits (e.g., DQ1[1], DQ1[2], and DQ1[3]) occur in the plurality of first bits BT1s, and the second error bit does not occur in the plurality of second bits BT2s, the control logic circuit 114 may control the output multiplexer circuit 113 to output the 1-3 bit DQ1[3] to the second sub-ECC circuit 112.

For example, when three first error bits (e.g., DQ1[1], DQ1[2], and DQ1[3]) occur in the plurality of first bits BT1s, and the second error bit does not occur in the plurality of second bits BT2s, the control logic circuit 114 may input the third selection signal SEL[2] with a value of “1” to the fifth output multiplexer MUX5 and the sixth output multiplexer MUX6.

Through this, the control logic circuit 114 may control the fifth output multiplexer MUX5 to output the 2-3 bit DQ2[3] to the first sub-ECC circuit 111. In addition, the control logic circuit 114 may control the sixth output multiplexer MUX6 to output the 1-3 bit DQ1[3] in which an error occurs to the second sub-ECC circuit 112.

In addition, the control logic circuit 114 may input selection signals having a value of “0”, excluding the third selection signal SEL[2], to the plurality of output multiplexers MUX1, MUX2, MUX3, MUX4, and MUX7 to MUX12.

Through this, the control logic circuit 114 may control the plurality of first bits BT1s excluding the 1-3 bit DQ1[3] to be input to the first sub-ECC circuit 111. In addition, the control logic circuit 114 may control the plurality of second bits BT2s excluding the 2-3 bit DQ2[3] to be input to the second sub-ECC circuit 112.

Furthermore, each of the first sub-ECC circuit 111 and the second sub-ECC circuit 112 may correct the error which includes input error bits, the number of which is less than or equal to the first number.

For example, the first sub-ECC circuit 111 may correct the 1-1 bit DQ1[1] and the 1-2 bit DQ1[2] in which an error occurs among the input bits.

In addition, the second sub-ECC circuit 112 may correct the 1-3 bit DQ1[3] in which an error occurs among the input bits.

According to embodiments of the present disclosure, when error bits occur, the number of which is less than or equal to the second number (e.g., ‘4’), among the plurality of bits BTs occur, the control logic circuit 114 may control the output multiplexer circuit 113 such that each of the first sub-ECC circuit 111 and the second sub-ECC circuit 112 receives and corrects error bits, the number of which is less than or equal to the first number (e.g., ‘2’).

Through this, the ECC circuit 110 may correct a relatively large number of error bits through a relatively small circuit configuration and a relatively small logic depth.

Therefore, the ECC circuit 110 according to an embodiment of the present disclosure may improve the performance (e.g., a read speed) and the yield of the memory device 120 (or the memory system 100).

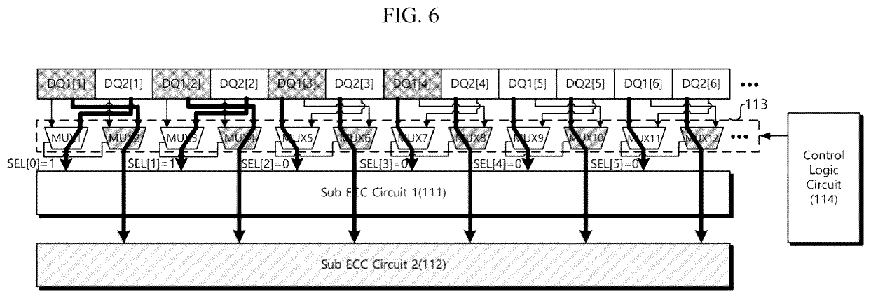

FIG. 6 illustrates a configuration in which a control logic circuit controls an output multiplexer circuit when the number of first error bits exceeds a first number and the number of second error bits is less than a first number, according to another embodiment.

As shown in FIG. 6, when first error bits exceeding the first number occur in the plurality of first bits BT1s, the control logic circuit 114 according to an embodiment may control the output multiplexer circuit 113 to output at least some of the first error bits to the second sub-ECC circuit 112.

In this case, it is assumed that each of the first sub-ECC circuit 111 and the second sub-ECC circuit 112 may correct the error which includes error bits, the number of which is less than or equal to the first number (e.g., ‘2’).

According to an embodiment, when four first error bits (e.g., DQ1[1], DQ1[2], DQ1[3], and DQ1[4]) occur in the plurality of first bits BT1s, and the second error bit does not occur in the plurality of second bits BT2s, the control logic circuit 114 may control the output multiplexer circuit 113 to output the 1-3 bit DQ1[3] and the 1-4 bit DQ1[4] to the second sub-ECC circuit 112.

For example, when four first error bits (e.g., DQ1[1], DQ1[2], DQ1[3], and DQ1[4]) occur in the plurality of first bits BT1s, and the second error bit does not occur in the plurality of second bits BT2s, the control logic circuit 114 may input the first selection signal SEL[0] with a value of “1” to the first output multiplexer MUX1 and the second output multiplexer MUX2. In addition, the control logic circuit 114 may input the second selection signal SEL[1] having a value of “1” to the third output multiplexer MUX3 and the fourth output multiplexer MUX4.

Through this, the control logic circuit 114 may control the first output multiplexer MUX1 to output the 2-1 bit DQ2[1] to the first sub-ECC circuit 111. In addition, the control logic circuit 114 may control the second output multiplexer MUX2 to output the 1-1 bit DQ1[1] in which an error occurs to the second sub-ECC circuit 112.

Through this, the control logic circuit 114 may control the third output multiplexer MUX3 to output the 2-2 bit DQ2[2] to the first sub-ECC circuit 111. In addition, the control logic circuit 114 may control the fourth output multiplexer MUX4 to output the 1-2 bit DQ1[2] in which an error occurs to the second sub-ECC circuit 112.

In addition, the control logic circuit 114 may input selection signals having a value of “0”, excluding the first selection signal SEL[0] and the second selection signal SEL[1], to the plurality of output multiplexers MUX5 to MUX12.

Through this, the control logic circuit 114 may input the plurality of first bits BT1s, excluding the 1-1 bit DQ1[1] and the 1-2 bit DQ1[2], to the first sub-ECC circuit 111. In addition, the control logic circuit 114 may input the plurality of second bits BT2s excluding the 2-1 bit DQ2[1] and the 2-2 bit DQ2[2] to the second sub-ECC circuit 112.

Furthermore, each of the first sub-ECC circuit 111 and the second sub-ECC circuit 112 may correct the error which includes input error bits, the number of which is less than or equal to the first number.

For example, the first sub-ECC circuit 111 may correct the 1-1 bit DQ1[1] and the 1-2 bit DQ1[2] in which an error occurs among the input bits.

In addition, the second sub-ECC circuit 112 may correct the 1-3 bit DQ1[3] and the 1-4 bit DQ1[4] in which an error occurs among the input bits.

According to embodiments of the present disclosure, when error bits occur, the number of which is less than or equal to the second number (e.g., ‘4’), among the plurality of bits BTs, the control logic circuit 114 may control the output multiplexer circuit 113 such that each of the first sub-ECC circuit 111 and the second sub-ECC circuit 112 receives and corrects error bits, the number of which is less than or equal to the first number (e.g., ‘2’).

Through this, the ECC circuit 110 may correct a relatively large number of error bits through a relatively small circuit configuration and a relatively small logic depth.

Therefore, the ECC circuit 110 according to an embodiment of the present disclosure may improve the performance (e.g., a read speed) and the yield of the memory device 120 (or the memory system 100).

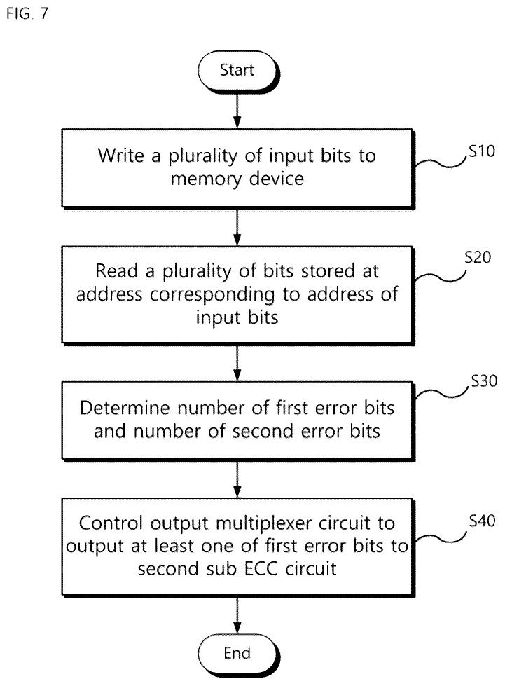

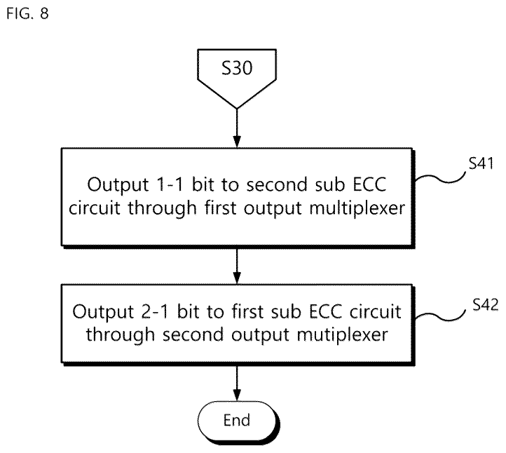

FIG. 7 is a flowchart illustrating an error correction method for a memory device, according to an embodiment. FIG. 8 is a flowchart illustrating a method of controlling multiplexers included in an output multiplexer circuit, according to an embodiment.

As shown in FIGS. 7 and 8 together, the ECC circuit 110 (or the control logic circuit 114) according to an embodiment may control the output multiplexer circuit 113 such that each of the first sub-ECC circuit 111 and the second sub-ECC circuit 112 receives and corrects error bits, the number of which is less than or equal to the first number (e.g., ‘2’).

As shown in FIG. 7, when first error bits exceeding the first number occur in the plurality of first bits BT1s, the ECC circuit 110 according to an embodiment may control the output multiplexer circuit 113 to output at least some of the first error bits to the second sub-ECC circuit 112.

In operation S10, the ECC circuit 110 according to an embodiment may store (write) a plurality of input bits in the memory device 120.

For example, the ECC circuit 110 may input the plurality of input bits in the memory device 120 through at least one ECC encoder.

In this case, the ECC circuit 110 may transmit a write request including the plurality of input bits and input address information corresponding to each of the plurality of input bits to the memory device 120.

According to an embodiment, two adjacent bits among the plurality of input bits may be stored in the memory device 120 with the same value.

For example, a 1-1 input bit and a 1-2 input bit may be stored in the memory device 120 with the same value. In addition, a 1-3 input bit and a 1-4 input bit may be stored in the memory device 120 with the same value.

In operation S20, the ECC circuit 110 according to an embodiment may read the plurality of bits BTs stored at addresses corresponding to the addresses of the plurality of input bits.

In more detail, the ECC circuit 110 may read the plurality of bits BTs stored in advance from the memory device 120. In this case, the plurality of bits BTs may include a plurality of data bits and a plurality of parity bits.

In operation S30, the ECC circuit 110 according to an embodiment may determine the number of first error bits and the number of second error bits.

In more detail, the ECC circuit 110 may determine the number of first error bits in which an error occurs among the plurality of first bits BT1s.

The ECC circuit 110 according to an embodiment may determine that, among the plurality of first bits BT1s, a bit having a value different from the value of the bit input to the corresponding address among the plurality of input bits is the first error bit.

For example, when the 1-1 input bit having an address value corresponding to the 1-1 bit DQ1[1] is input to the memory device 120 with a value of “0”, but the 1-1 bit DQ1[1] is output from the memory device 120 with a value of “1”, the ECC circuit 110 may determine the 1-1 bit DQ1[1] as the first error bit.

For another example, when the 1-1 input bit having an address value corresponding to the 1-1 bit DQ1[1] is input to the memory device 120 with a value of “0”, and the 1-1 bit DQ1[1] is output from the memory device 120 with a value of “0”, the ECC circuit 110 may determine that there is no error in the 1-1 bit DQ1[1].

In addition, the ECC circuit 110 may determine the number of second error bits in which an error occurs among the plurality of second bits BT2s.

The ECC circuit 110 according to an embodiment may determine that, among the plurality of second bits BT2s, a bit having a value different from the value of the bit input to the corresponding address among the plurality of input bits is the second error bit.

For example, when the 2-3 input bit having an address value corresponding to the 2-3 bit DQ2[3] is input to the memory device 120 with a value of “1”, but the 2-3 bit DQ2[3] is output from the memory device 120 with a value of “0”, the ECC circuit 110 may determine that the 2-3 bit DQ2[3] is the second error bit.

The ECC circuit 110 according to an embodiment may determine whether an error occurs in each of the plurality of first bits BT1s and the plurality of second bits BT2s, thereby determining the numbers of first error bits and the second error bits, respectively.

For example, the ECC circuit 110 may determine that an error occurs in three bits of the plurality of first bits BT1s. In detail, the ECC circuit 110 may determine that three first error bits among the plurality of first bits BT1s occur.

In addition, the ECC circuit 110 may determine that an error occurs in one bit among the plurality of second bits BT2s. In detail, the ECC circuit 110 may determine that one second error bit among the plurality of second bits BT2s occurs.

In operation S40, the ECC circuit 110 according to an embodiment may control the output multiplexer circuit 113 to output at least one of the first error bits to the second sub-ECC circuit 112.

In more detail, when first error bits exceeding the first number occur in the plurality of first bits BT1s, and second error bits, the number of which is less than the first number, occur in the plurality of second bits BT2s, the ECC circuit 110 may control the output multiplexer circuit 113 to output at least one of the first error bits to the second sub-ECC circuit 112.

In this case, it is assumed that each of the first sub-ECC circuit 111 and the second sub-ECC circuit 112 may correct the error which includes error bits, the number of which is less than or equal to the first number (e.g., ‘2’).

As shown in FIG. 8, when three first error bits (e.g., DQ1[1], DQ1[2], and DQ1[3]) occur in the plurality of first bits BT1s, and one second error bit (e.g., DQ2[6]) occurs in the plurality of second bits BT2s, the ECC circuit 110 may control the output multiplexer circuit 113 to output the 1-1 bit DQ1[1] to the second sub-ECC circuit 112.

In operation S41, the ECC circuit 110 may output the 1-1 bit DQ1[1] to the second sub-ECC circuit 112 through the first output multiplexer MUX1.

For example, the ECC circuit 110 may input the first selection signal SEL[0] having a value of “1” to the first output multiplexer MUX1. Through this, the ECC circuit 110 may control the first output multiplexer MUX1 to output the 1-1 bit DQ1[1] in which an error occurs to the second sub-ECC circuit 112.

In operation S42, the ECC circuit 110 may output the 2-1 bit DQ2[1] to the first sub-ECC circuit 111 through the second output multiplexer MUX2.

For example, the ECC circuit 110 may input the first selection signal SEL[0] having a value of “1” to the second output multiplexer MUX2. In this case, the second output multiplexer MUX2 may output the 2-1 bit DQ2[1] to the first sub-ECC circuit 111.

In addition, the ECC circuit 110 may input selection signals having a value of “0”, excluding the first selection signal SEL[0], to the plurality of output multiplexers MUX3 to MUX12.

Through this, the control logic circuit 114 may control the plurality of first bits BT1s excluding the 1-1 bit DQ1[1] to be input to the first sub-ECC circuit 111. In addition, the control logic circuit 114 may control the plurality of second bits BT2s excluding the 2-1 bit DQ2[1] to be input to the second sub-ECC circuit 112.

Furthermore, each of the first sub-ECC circuit 111 and the second sub-ECC circuit 112 according to an embodiment may correct the error which includes input error bits, the number of which is less than or equal to the first number.

For example, the first sub-ECC circuit 111 may correct the 1-2 bit DQ1[2] and the 1-3 bit DQ1[3] in which an error occurs among the input bits.

In addition, the second sub-ECC circuit 112 may correct the 2-6 bit DQ2[6] and the 1-1 bit DQ1[1] in which an error occurs among the input bits.

According to embodiments of the present disclosure, when error bits occur, the number of which is less than or equal to the second number (e.g., ‘4’), among the plurality of bits BTs, the control logic circuit 114 may control the output multiplexer circuit 113 such that each of the first sub-ECC circuit 111 and the second sub-ECC circuit 112 receives and corrects error bits, the number of which is less than or equal to the first number (e.g., ‘2’).

Through this, the ECC circuit 110 may correct a relatively large number of error bits through a relatively small circuit configuration and a relatively small logic depth.

Therefore, the ECC circuit 110 according to an embodiment of the present disclosure may improve the performance (e.g., a read speed) and the yield of the memory device 120 (or the memory system 100).

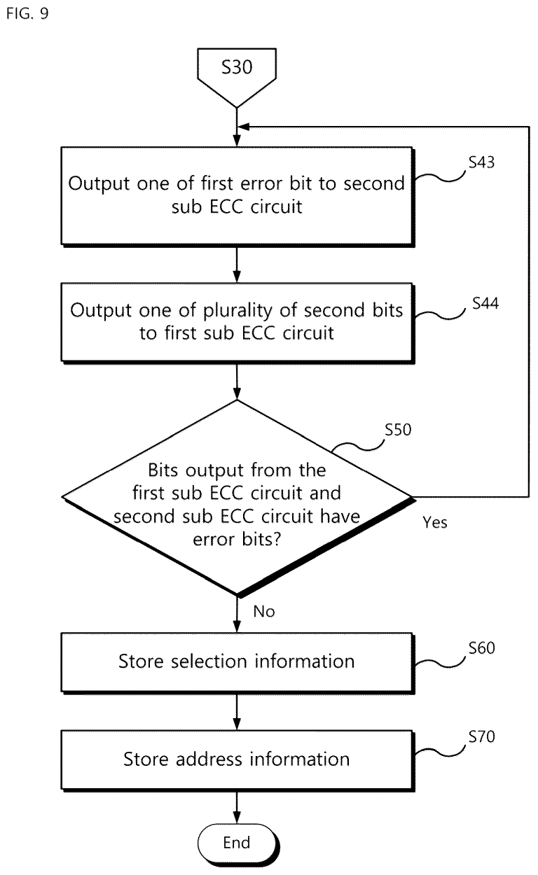

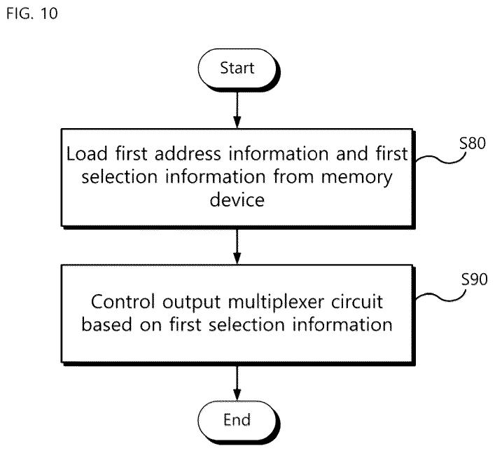

FIG. 9 is a flowchart illustrating a method of storing selection information and address information according to values of a plurality of bits, according to an embodiment. FIG. 10 is a flowchart illustrating a method of controlling an output multiplexer circuit based on stored address information and stored selection information, according to an embodiment.

As shown in FIGS. 9 and 10, the ECC circuit 110 according to an embodiment may store address information and selection information based on whether an error occurs in the plurality of bits BTs. Furthermore, the ECC circuit 110 may control the output multiplexer circuit 113 based on selection information stored in response to address information.

In operation S43, the ECC circuit 110 according to an embodiment may output one bit among the first error bits to the second sub-ECC circuit 112.

In more detail, when the number of first error bits exceeds the first number and the number of second error bits is less than the first number, the ECC circuit 110 may control the output multiplexer circuit 113 to output one bit of the first error bits to the second sub-ECC circuit 112.

In addition, in operation S44, the ECC circuit 110 according to an embodiment may output one bit among the plurality of second bits BT2s to the first sub-ECC circuit 111.

In more detail, the ECC circuit 110 may control the output multiplexer circuit 113 to output a bit input to the multiplexer that is the same as one of the first error bits among the plurality of second bits BT2s to the first sub-ECC circuit 111.

For example, the ECC circuit 110 may control the output multiplexer circuit 113 to output the 1-1 bit DQ1[1] in which an error occurs to the second sub-ECC circuit 112.

In addition, the ECC circuit 110 may control the output multiplexer circuit 113 to output the 2-1 bit DQ2[1] input to the multiplexer (e.g., MUX1 or MUX2) that is the same as the 1-1 bit DQ1[1] to the first sub-ECC circuit 111.

In this case, it is assumed that there is no error in the 2-1 bit DQ2[1].

Furthermore, in operation S50, the ECC circuit 110 according to an embodiment may determine whether an error bit exists among the bits output from the first sub-ECC circuit 111 and the second sub-ECC circuit 112.

In more detail, the ECC circuit 110 may determine whether there is a bit with a value different from the value of the bit input to the corresponding address in the plurality of input bits, among the bits output from the first sub-ECC circuit 111 and the second sub-ECC circuit 112.

In detail, the ECC circuit 110 may determine whether an error bit output with a value different from the value of the bit input to the corresponding address exists, among the bits output from the first sub-ECC circuit 111 and the second sub-ECC circuit 112.

In this case, when an error bit exists among the bits output from the first sub-ECC circuit 111 and the second sub-ECC circuit 112, the ECC circuit 110 may output one bit of the first error bits to the second sub-ECC circuit 112.

For example, when the value decreased by 1 from the number of first error bits exceeds the first number and the value increased by 1 from the number of second error bits is less than the first number, the ECC circuit 110 may output the 1-2 bit DQ1[2] in which an error occurs to the second sub-ECC circuit 112 through the fourth output multiplexer MUX4.

In addition, the ECC circuit 110 may output one of bits in which an error does not occur among the plurality of second bits BT2s to the first sub-ECC circuit 111. For example, the ECC circuit 110 may output the 2-2 bit DQ2[2] in which an error does not occur to the first sub-ECC circuit 111 through the third output multiplexer MUX3.

In operation S60, according to an embodiment, when there is no error bit among the bits output from the first sub-ECC circuit 111 and the second sub-ECC circuit 112, the ECC circuit 110 may store selection information.

In more detail, when there is no error bit among the bits output from the first sub-ECC circuit 111 and the second sub-ECC circuit 112, the ECC circuit 110 may store selection information about selection signals transmitted to the output multiplexer circuit 113.

When each of the bits output from the first sub-ECC circuit 111 and the second sub-ECC circuit 112 is output with the same value as the input bits input to the corresponding address, the ECC circuit 110 may store selection information about selection signals transmitted to the output multiplexer circuit 113.

In this case, for example, the ECC circuit 110 may store selection information including information about selection signals transmitted to the output multiplexer circuit 113 in the memory device 120 to control the output multiplexer circuit 113.

For example, the ECC circuit 110 may store selection information including information about selection signals transmitted to the output multiplexer circuit 113 in a one time programmable (OTP) block included in the memory device 120.

In addition, in operation S70, the ECC circuit 110 according to an embodiment may store address information.

In more detail, the ECC circuit 110 may match the address information including the address values of each of the first error bits and/or the second error bits output from the memory device 120 with the selection information to be stored in the memory device 120.

For example, when an error occurs in the 1-1 bit DQ1[1], and the error is corrected through the first sub-ECC circuit 111 or the second sub-ECC circuit 112, the ECC circuit 110 may store address information including the address value of the 1-1 bit DQ1[1] in the memory device 120 in correspondence with selection information including values of selection signals for error correction.

In this case, for example, the ECC circuit 110 may store the address information including address values of error bits in which an error occurs among the plurality of bits BTs in the memory device 120 (or the OTP block).

In detail, when the ECC circuit 110 controls the output multiplexer circuit 113 to correct the error which includes error bits among the plurality of bits BTs, the ECC circuit 110 may store the address information of the error bits in which an error occurs and selection information including values of selection signals generated to control the output multiplexer circuit 113 in correspondence with each other.

According to embodiments of the present disclosure, the ECC circuit 110 may control the output multiplexer circuit 113 when error bits occur, the number of which is less than or equal to the second number, and may store selection information for correcting the error in the error bits and address information of the error bits.

Furthermore, the ECC circuit 110 may control the output multiplexer circuit 113 based on the stored selection information and the stored address information. Through this, the ECC circuit 110 may correct the error in bits read according to the operation of the memory device 120.

As shown in FIG. 10, the ECC circuit 110 according to an embodiment may correct error bits based on selection information and address information stored in the memory device 120.

In operation S80, the ECC circuit 110 may load first selection information and first address information from the memory device 120.

In more detail, in response to an operation request for the memory device 120 being input, the ECC circuit 110 may identify the first address information corresponding to the operation request among address information stored in the memory device 120.

In this case, the operation request includes an address value and may be understood as a signal (or request) requesting an operation on an address corresponding to the address value among address information stored in the memory device 120.

For example, the operation request may be understood as a write request requesting to store data at a specific address of the memory device 120. In this case, the operation request may include the address value of the address requesting to store data.

As another example, the operation request may be understood as a read request requesting to read data stored at a specific address of the memory device 120. In this case, the operation request may include the address value of an address requesting to read data.

However, the type and configuration of the operation request are not limited to the examples described above.

For example, the ECC circuit 110 may identify first address information corresponding to an address value “17′h107” included in the operation request among the address information stored in the memory device 120.

Furthermore, the ECC circuit 110 may load the first address information and the first selection information stored in correspondence with the first address information from the memory device 120.

In more detail, the ECC circuit 110 may load the first address information corresponding to the address value included in the operation request and the first selection information stored in correspondence with the first address information from the memory device 120.

In this case, the first selection information may be understood as including data about the selection signal for controlling the output multiplexer circuit 113 to correct the error when an error occurs in data stored at addresses included in the first address information.

For example, the ECC circuit 110 may load first address information corresponding to the address value “17′h107” included in the operation request among the address information stored in the memory device 120 and first selection information “32′b10000001000000000000000000000000” stored in correspondence with the address value “17′h107” from the memory device 120.

Furthermore, in operation S90, the ECC circuit 110 may control the output multiplexer circuit 113 based on the first selection information.

In more detail, the ECC circuit 110 may control the output multiplexer circuit 113 based on the first selection information loaded from the memory device 120. Through this, the ECC circuit 110 may correct error bits that occur while the memory device 120 operates in response to the operation request.

For example, the ECC circuit 110 may control at least some of the plurality of output multiplexers MUX1 to MUX12 included in the output multiplexer circuit 113 based on the first selection information “32′b10000001000000000000000000000000”.

According to embodiments of the present disclosure, the ECC circuit 110 may determine the first address information and first selection information corresponding to the address value included in the operation request among the information stored in the memory device 120 in response to a request requesting an operation for a specific address of the memory device 120.

Furthermore, the ECC circuit 110 may control the output multiplexer circuit 113 based on the first selection information.

Through this, the ECC circuit 110 may correct the error which includes generated error bits as the memory device 120 operates in response to an operation request.

Accordingly, the ECC circuit 110 (or the memory system 100) according to an embodiment of the present disclosure may reduce the time required to correct error bits that occur according to an operation of the memory device 120.

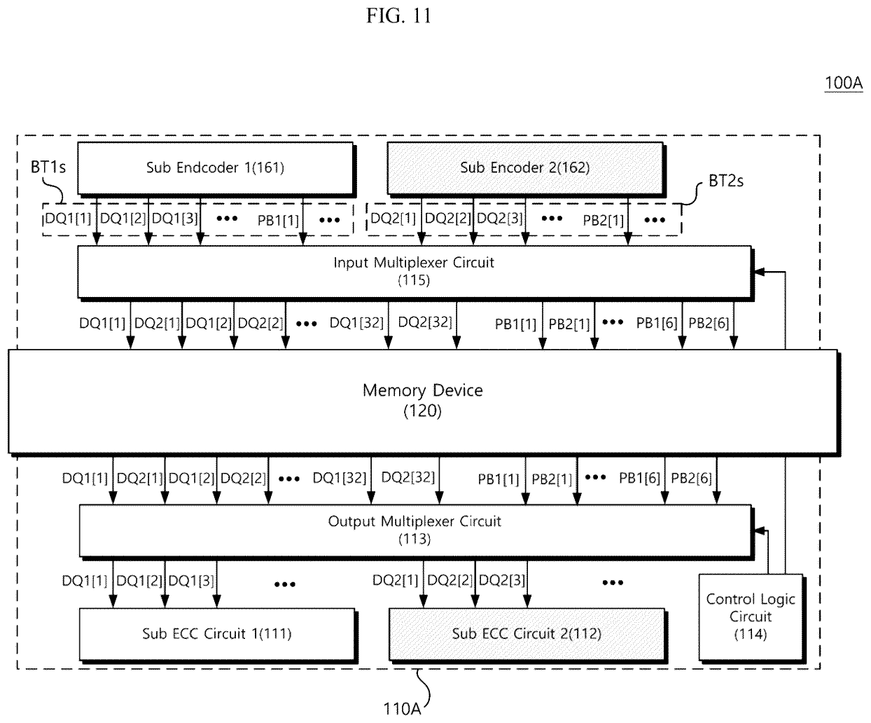

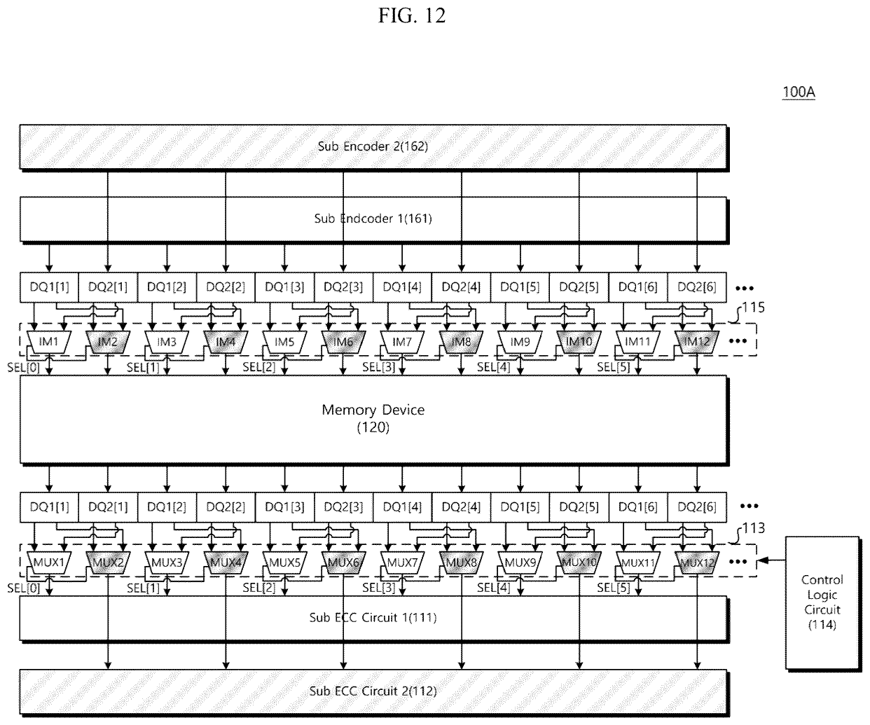

FIG. 11 is a block diagram illustrating a memory system, according to an embodiment. FIG. 12 illustrates a configuration in which a control logic circuit controls an input multiplexer and an output multiplexer, according to an embodiment.

As shown in FIGS. 11 and 12 together, a memory system 100A according to an embodiment may include an ECC circuit 110A and the memory device 120.

In this case, the memory system 100A illustrated in FIGS. 11 and 12 may be understood as an example of the memory system 100 illustrated in FIGS. 1A and 1B. Accordingly, the same reference numerals are used for components that are the same or actually the same as the above-described components, and additional descriptions that overlap with the above-described content will be omitted to avoid redundancy.

The memory system 100A may include the ECC circuit 110A connected to the memory device 120.

According to an embodiment, the ECC circuit 110A may include the first sub-ECC circuit 111, the second sub-ECC circuit 112, the output multiplexer circuit 113, an input multiplexer circuit 115, a first sub-encoder 161, a second sub-encoder 162, and the control logic circuit 114.

The control logic circuit 114 may control the input multiplexer circuit 115 and the output multiplexer circuit 113.

As shown in FIG. 12, the control logic circuit 114 may control the input multiplexer circuit 115 and the output multiplexer circuit 113 by outputting a plurality of selection signals.

According to an embodiment, the control logic circuit 114 may control the input multiplexer circuit 115 to transmit the plurality of first bits BT1s input through the first sub-encoder 161 and the plurality of second bits BT2s input through the second sub-encoder 162 to the memory device 120.

In addition, when first error bits exceeding the first number occur in the plurality of first bits BT1s, the control logic circuit 114 according to an embodiment may control the output multiplexer circuit 113 to output at least one of the first error bits to the second sub-ECC circuit 112.

For example, when first error bits exceeding the first number occur in the plurality of first bits BT1s, the control logic circuit 114 may control at least some of the output multiplexers of the output multiplexer circuit 113 to output at least one of the first error bits to the second sub-ECC circuit 112.

In addition, the control logic circuit 114 may control the input multiplexer circuit 115 to correspond to the output multiplexer circuit 113 in response to controlling the output multiplexer circuit 113.

In more detail, when the output multiplexer circuit 113 is controlled, the control logic circuit 114 may control the input multiplexers corresponding to the output multiplexers of the output multiplexer circuit 113 among the input multiplexers of the input multiplexer circuit 115.

According to an embodiment, when first error bits exceeding the first number occur in the plurality of first bits BT1s, and second error bits, the number of which is less than the first number, occur in the plurality of second bits BT2s, the control logic circuit 114 may control the output multiplexer circuit 113 to output at least some of the first error bits to the second sub-ECC circuit 112.

In this case, it is assumed that each of the first sub-ECC circuit 111 and the second sub-ECC circuit 112 may correct the error which includes error bits, the number of which is less than or equal to the first number (e.g., ‘2’).

When three first error bits (e.g., DQ1[1], DQ1[2], and DQ1[3]) occur in the plurality of first bits BT1s, and one second error bit (e.g., DQ2[1]) occurs in the plurality of second bits BT2s, the control logic circuit 114 may control the output multiplexer circuit 113 to output the 1-3 bit DQ1[3] to the second sub-ECC circuit 112.

When three first error bits (e.g., DQ1[1], DQ1[2], and DQ1[3]) occur in the plurality of first bits BTs, and one second error bit (e.g., DQ2[1]) occurs in the plurality of second bits BT2s, the control logic circuit 114 may input the third selection signal SEL[2] with a value of “1” to the fifth output multiplexer MUX5 and the sixth output multiplexer MUX6.

Through this, the control logic circuit 114 may control the fifth output multiplexer MUX5 to output the 2-3 bit DQ2[3] to the first sub-ECC circuit 111. In addition, the control logic circuit 114 may control the sixth output multiplexer MUX6 to output the 1-3 bit DQ1[3] in which an error occurs to the second sub-ECC circuit 112.

In addition, along with this, the control logic circuit 114 may input the third selection signal SEL[2] with a value of “1” to a fifth input multiplexer IM5 and a sixth input multiplexer IM6.

In addition, the control logic circuit 114 may input selection signals having a value of “0”, excluding the third selection signal SEL[2], to the plurality of output multiplexers MUX1, MUX2, MUX3, MUX4, and MUX7 to MUX12.

In addition, along with this, the control logic circuit 114 may input the selection signals having a value of “0”, excluding the third selection signal SEL[2], to a plurality of input multiplexers IM1, IM2, IM3, IM4, and IM7 to IM12.

According to embodiments of the present disclosure, the control logic circuit 114 may control the output multiplexer circuit 113 such that each of the first sub-ECC circuit 111 and the second sub-ECC circuit 112 corrects the error which includes error bits, the number of which is less than or equal to the first number (e.g., ‘2’).

Through this, the ECC circuit 110A may correct a relatively large number of error bits through a relatively small circuit configuration.

Accordingly, the ECC circuit 110A according to an embodiment of the present disclosure may improve the operation speed of the memory device 120 (or the memory system 100) by having a relatively small circuit configuration. In addition, the ECC circuit 110A may improve the yield of the memory device 120 (or the memory system 100) by increasing the number of bits capable of error correction.

In addition, along with this, the control logic circuit 114 may control the input multiplexers IM1 to IM12 included in the input multiplexer circuit 115 to correspond to the output multiplexers MUX1 to MUX12 included in the output multiplexer circuit 113.

In detail, the control logic circuit 114 may control the output multiplexer circuit 113 and the input multiplexer circuit 115 together using the plurality of selection signals SEL[0] to SEL[5].

Accordingly, when viewed from a system or layer outside the memory system 100A, the control logic circuit 114 may control the output multiplexer circuit 113 and the input multiplexer circuit 115 together such that it is determined that each of the plurality of bits BT1s and BT2s are written to and read from the memory device 120 depending on a preset address.

Through this, the memory system 100A according to an embodiment of the present disclosure may prevent an address mismatch between the memory system 100A and a system or layer outside the memory system 100A due to a change in the transmission path of the bit.

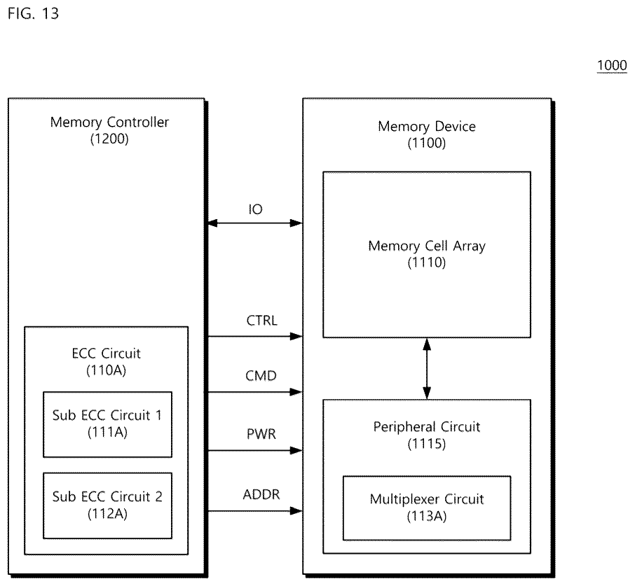

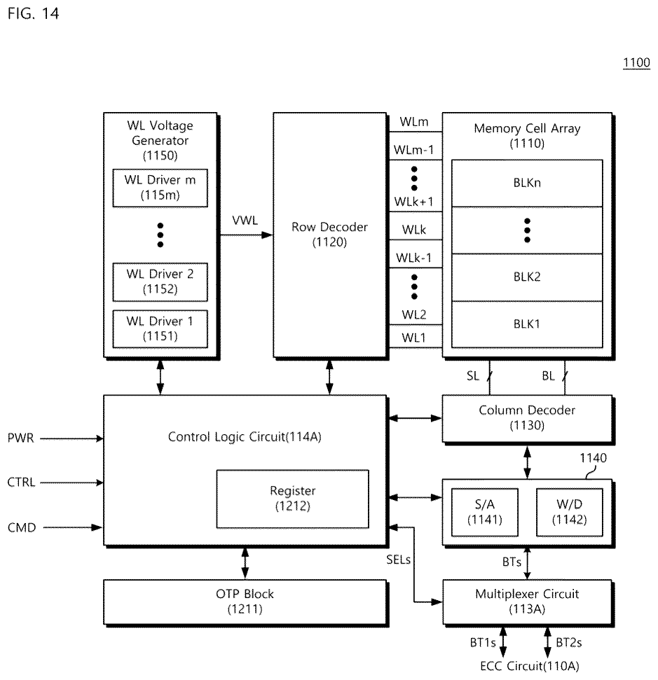

FIG. 13 is a block diagram illustrating a memory system including a memory controller and a memory device, according to an embodiment. FIG. 14 is a block diagram illustrating a configuration of a memory device in FIG. 13.

As shown in FIG. 13, a memory system 1000 may include a memory device 1100 and a memory controller 1200.

The memory system 1000 of FIG. 13 may be a resistive storage device based on a resistive memory. For example, the memory device 1100 may be an MRAM, a ReRAM, or a PRAM.

The memory device 1100 may receive input/output signals IO through input/output lines, may receive control signals CTRL through control lines, and may receive an external power PWR through power lines, from the memory controller 1200.

The memory system 1000 may store data in the memory device 1100 under a control of the memory controller 1200.

According to an embodiment, the memory controller 1200 may include the ECC circuit 110A. In addition, the ECC circuit 110A may include a first sub-ECC circuit 111A and a second sub-ECC circuit 112A.

In this case, the ECC circuit 110A illustrated in FIG. 13 may be understood as an example of the ECC circuit 110 illustrated in FIG. 1A. Therefore, descriptions that overlap with the above-described content will be omitted to avoid redundancy.

According to an embodiment, the ECC circuit 110A may correct error bits included in bits output from the memory device 1100.

In more detail, the ECC circuit 110A may correct the error that occur in the process of storing data in the memory device 1100 and reading data from the memory device 1100.

The first sub-ECC circuit 111A according to an embodiment may correct error bits, the number of which is less than or equal to the first number (e.g., ‘2’). In addition, the second sub-ECC circuit 112A may correct error bits, the number of which is less than or equal to the first number.

Accordingly, the ECC circuit 110A may correct error bits, the number of which is less than or equal to a second number (e.g., ‘4’) that is twice the first number, among bits output from the memory device 1100.

The memory device 1100 may include a memory cell array 1110 and a peripheral circuit 1115. The memory cell array 1110 may have a planar two-dimensional structure or a vertical three-dimensional structure. The memory cell array 1110 may be composed of a plurality of memory cells. Each memory cell may store single-bit data or multi-bit data.

The memory cell array 1110 may be located next to or above the peripheral circuit 1115 in the design arrangement structure. The structure in which the memory cell array 1110 is located on the peripheral circuit 1115 is called a COP (cell on peripheral) structure. The memory cell array 1110 may be manufactured as a separate chip from the peripheral circuit 1115. An upper chip including the memory cell array 1110 and a lower chip including the peripheral circuit 1115 may be connected to each other by a bonding method. This structure is called C2C (chip to chip) structure.

The peripheral circuit 1115 may include all analog circuits or digital circuits required to store data in the memory cell array 1110 or read data stored in the memory cell array 1110. The peripheral circuit 1115 may receive the external power PWR input through the power lines and may generate various levels of internal powers.

The peripheral circuit 1115 may receive commands, addresses, and data from the memory controller 1200 through the input/output lines. The peripheral circuit 1115 may store data in the memory cell array 1110 depending on the control signals CTRL. In addition, the peripheral circuit 1115 may read data stored in the memory cell array 1110 and may provide read data to the memory controller 1200.

According to an embodiment, the peripheral circuit 1115 may include an output multiplexer circuit 113A.

The output multiplexer circuit 113A according to an embodiment may transmit at least some of the data bits (or parity bits) output from the memory cell array 1110 to the ECC circuit 110A.

As shown in FIGS. 13 and 14 together, the memory device 1100 may include the memory cell array 1110 and the peripheral circuit 1115. The peripheral circuit 1115 may include a row decoder 1120, a column decoder 1130, an input/output circuit 1140, a word line voltage generator 1150, a control logic circuit 114A, and an OTP block 1211.

The memory cell array 1110 may include a plurality of memory blocks BLK1 to BLKn. Each memory block may be composed of a plurality of memory cells. Each memory cell may store multi-bit data. Each memory block (e.g., BLK1) may be connected to a plurality of word lines WL1 to WLm.

The row decoder 1120 may be connected to the memory cell array 1110 through the plurality of word lines WL1 to WLm. The row decoder 1120 may select a word line during a program operation or a read operation. The row decoder 1120 may receive a word line voltage VWL from the word line voltage generator 1150 and may provide the word line voltage VWL for a program operation or a read operation to the selected word line.

The column decoder 1130 may be connected to the memory cell array 1110 through source lines SL and/or bit lines BL. The column decoder 1130 may select the source line SL or the bit line BL in response to a selection signal provided from the control logic circuit 114A. The column decoder 1130 may select the source line SL or the bit line BL using a plurality of NMOS transistors (not illustrated).

The input/output circuit 1140 may be internally connected to the column decoder 1130 through data lines, and may be externally connected to the ECC circuit 110A (or the memory controller 1200).

The input/output circuit 1140 may receive program data from the memory controller 1200 during a program operation. In addition, the input/output circuit 1140 may provide at least some of the data read from the memory cell array 1110 to the memory controller 1200 during a read operation.

For example, the input/output circuit 1140 may provide at least some of the bits read from the memory cell array 1110 to the ECC circuit 110A through the output multiplexer circuit 113A.

The input/output circuit 1140 may include a sense amplifier 1141 and a write driver 1142. The input/output circuit 1140 may provide data to the write driver 1142 in response to a control signal or may output data provided from the sense amplifier 1141 to the outside.

The sense amplifier 1141 may read data stored in the selected memory cell by sensing a difference between a voltage of the source line SL and a reference voltage Vref during a read operation. In this case, the reference voltage Vref may be provided from a reference voltage generator circuit (not illustrated). The sense amplifier 1141 may operate in response to a control signal provided from the control logic circuit 114A.

The write driver 1142 may receive a control signal from the control logic circuit 114A and may provide a program current I_PGM to the memory cell array 1110. In this case, the program current I_PGM is used to program the selected memory cell into one of multi-states. During an MLC program operation, the write driver 1142 may provide the program current I_PGM once or more depending on the multi-state of the selected memory cell.

The word line voltage generator 1150 may receive internal power from the control logic circuit 114A and may generate the word line voltage VWL required to read or write data. The word line voltage VWL may be provided to a selected word line sWL through the row decoder 1120. The word line voltage generator 1150 may include a plurality of word line drivers 1151 to 115m.

The OTP block 1211 may store address information of a memory block or a memory cell in the memory cell array 1110 in which an error bit is output during operation of the memory device 1100.

For example, when error bits are output from the memory cell array 1110, the OTP block 1211 may store address information including the address value of the memory block or the memory cell in which each of the error bits is output.

In addition, when error bits are output, the OTP block 1211 may store selection information about selection signals SELs that are transmitted to the output multiplexer circuit 113A to correct the error bits by controlling the output multiplexer circuit 113A.

For example, when error bits are output from the memory cell array 1110, the OTP block 1211 may store selection information about the selection signals SELs when all error bits may be corrected through the ECC circuit 110A by controlling the output multiplexer circuit 113A.

In this case, the selection information may be stored in the OTP block 1211 in correspondence with the address information.

The control logic circuit 114A may control a read operation and/or a write operation of the memory device 1100 using commands CMD, addresses ADDR, and control signals CTRL provided from the memory controller 1200 (or the ECC circuit 110A). The addresses ADDR may include a row address for selecting one memory block or one word line, and a column address for selecting one memory cell.

The control logic circuit 114A may include a register 1212.

The control logic circuit 114A may load information stored in the OTP block 1211 through the register 1212 in response to the operation of the memory system 1000 (or the memory device 1100).

In more detail, the control logic circuit 114A may load address information and selection information stored in the OTP block 1211 through the register 1212 in response to the operation of the memory system 1000.

Furthermore, the control logic circuit 114A may control the output multiplexer circuit 113A using address information and selection information loaded from the OTP block 1211 through the register 1212.

For example, when first error bits exceeding the first number occur in the plurality of first bits BT1s, the control logic circuit 114A may control the output multiplexer circuit 113A to output at least one of the first error bits to the second sub-ECC circuit 112A.

In more detail, when first error bits exceeding the first number occur in the plurality of first bits BT1s, and second error bits, the number of which is less than the first number, occur in the plurality of second bits BT2s, the control logic circuit 114A may control the output multiplexer circuit 113A to output at least one of the first error bits to the second sub-ECC circuit 112A.

In this case, it is assumed that each of the first sub-ECC circuit 111A and the second sub-ECC circuit 112A may correct the error which includes error bits, the number of which is less than or equal to the first number (e.g., ‘2’).

When the number of error bits is less than or equal to the second number (e.g., ‘4’) that is twice the first number, among the plurality of bits BTs occur, the control logic circuit 114A may control the output multiplexer circuit 113A such that each of the first sub-ECC circuit 111A and the second sub-ECC circuit 112A receives and corrects error bits, the number of which is less than or equal to the first number (e.g., ‘2’).

Through this, the ECC circuit 110A may correct a relatively large number of error bits through a relatively small circuit configuration and a relatively small logic depth.

Therefore, the ECC circuit 110A according to an embodiment of the present disclosure may improve the performance (e.g., a read speed) and the yield of the memory device 1100 (or the memory system 1000).

As described herein, when the number of error bits is less than or equal to the second number, among the plurality of bits BTs occur, the control logic circuit 114A according to an embodiment of the present disclosure may control the output multiplexer circuit 113A such that each of the first sub-ECC circuit 111 and the second sub-ECC circuit 112 may receive and correct error bits, the number of which is less than or equal to the first number.

In detail, the ECC circuit 110 may correct a relatively large number of error bits through a relatively small circuit configuration.

Accordingly, the ECC circuit 110 according to an embodiment of the present disclosure may improve the operation speed of the memory device 120 (or the memory system 100) by having a relatively small circuit configuration.

In addition, the ECC circuit 110 may improve the yield of the memory device 120 (or the memory system 100) by increasing the number of bits capable of error correction.

In addition, the ECC circuit 110 according to an embodiment may determine first address information and first selection information corresponding to the address value included in an operation request among information stored in the memory device 120 in response to a request for requesting an operation with respect to a specific address of the memory device 120. Furthermore, the ECC circuit 110 may control the output multiplexer circuit 113 based on the first selection information.

Through this, the ECC circuit 110 may correct the error which includes generated error bits when the memory device 120 operates in response to an operation request.

Accordingly, the ECC circuit 110 (or the memory system 100) according to an embodiment of the present disclosure may reduce the time required to correct error bits that occur according to an operation of the memory device 120.

According to an embodiment of the present disclosure, the ECC circuit may improve the operation speed of the memory system and the number of bits capable of error correction. Through this, the ECC circuit may improve the yield and performance of the memory device.

The above descriptions are specific embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure. While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An error correction code (ECC) circuit connected to a memory device, the ECC circuit comprising:
a first sub-ECC circuit configured to correct a first error which includes first error bits;
a second sub-ECC circuit configured to correct a second error which includes second error bits;
an output multiplexer circuit configured to output a plurality of bits, wherein a first plurality of bits among the plurality of bits is output to the first sub-ECC circuit, and wherein a second plurality of bits among the plurality of bits is output to the second sub-ECC circuit; and
a control logic circuit configured to control the output multiplexer circuit, and
wherein the control logic circuit is further configured to:
control the output multiplexer circuit to output at least one of the first error bits to the second sub-ECC circuit based on a number of the first error bits exceeding a first number and a number of the second error bits is less than the first number.

2. The ECC circuit of claim 1, wherein the output multiplexer circuit comprises:
a first output multiplexer configured to receive a 1-1 bit and a 2-1 bit to be output to the first sub-ECC circuit; and
a second output multiplexer configured to receive the 1-1 bit and the 2-1 bit to be output to the second sub-ECC circuit, and
wherein, based on the number of the first error bits being less than or equal to the first number and the number of the second error bits being less than or equal to the first number, the control logic circuit is further configured to:
output the 1-1 bit to the first sub-ECC circuit through the first output multiplexer; and
output the 2-1 bit to the second sub-ECC circuit through the second output multiplexer.

3. The ECC circuit of claim 2, wherein, based on the first error bits comprising the 1-1 bit and the second error bits not comprising the 2-1 bit, and in response to the number of the first error bits exceeding the first number and the number of the second error bits being less than the first number, the control logic circuit is further configured to;
output the 2-1 bit to the first sub-ECC circuit through the first output multiplexer; and
output the 1-1 bit to the second sub-ECC circuit through the second output multiplexer.

4. The ECC circuit of claim 3, wherein the output multiplexer circuit further comprises:
a third output multiplexer configured to receive a 1-2 bit and a 2-2 bit to be output to the first sub-ECC circuit; and
a fourth output multiplexer configured to receive the 1-2 bit and the 2-2 bit to be output to the second sub-ECC circuit, and
wherein, the number of the first error bits decreased by one exceeding the first number and the number of the second error bits increased by one being less than the first number, the control logic circuit is further configured to:
output the 2-2 bit to the first sub-ECC circuit through the third output multiplexer; and
output the 1-2 bit to the second sub-ECC circuit through the fourth output multiplexer.

5. The ECC circuit of claim 3, wherein, when there are no error bits among bits output from the first sub-ECC circuit and the second sub-ECC circuit, the control logic circuit is further configured to:
store selection information about a selection signal transmitted to the output multiplexer circuit in the memory device.

6. The ECC circuit of claim 5, wherein the control logic circuit is further configured to store address information of the first error bits and the second error bits output from the memory device in correspondence with the selection information in the memory device.

7. The ECC circuit of claim 6, wherein the control logic circuit is further configured to:
in response to receiving an operation request for the memory device, load first selection information from the memory device, wherein the first selection information is stored in correspondence with first address information associated with an address value included in the operation request; and
control the output multiplexer circuit based on the first selection information.

8. The ECC circuit of claim 1, wherein the control logic circuit is further configured to:
identify first bits among the first plurality of bits as the first error bits, the first bits having a data value different from a bit having a corresponding address value among a plurality of input bits input to the memory device; and
identify second bits among the second plurality of bits as the second error bits, the second bits having a data value different from a bit having a corresponding address value among the plurality of input bits.

9. The ECC circuit of claim 1, wherein the first plurality of bits comprises a plurality of first data bits and a plurality of first parity bits,
wherein the second plurality of bits comprises a plurality of second data bits and a plurality of second parity bits,
wherein the first sub-ECC circuit corrects one or more errors in input error bits using at least some of the plurality of first parity bits, and
wherein the second sub-ECC circuit corrects the one or more errors in the input error bits using at least some of the plurality of second parity bits.

10. The ECC circuit of claim 1, wherein the first plurality of bits and the second plurality of bits each include a same number of bits.

11. A method of performing an error correction for a plurality of bits read from a memory device, the method comprising:
storing a plurality of input bits in the memory device;
reading a plurality of bits stored at an address corresponding to an address value of the plurality of input bits from the memory device;
determining a number of first error bits occurring in a first plurality of bits among the plurality of bits in which a first sub-ECC circuit is error-correctable, and a number of second error bits occurring in a second plurality of bits among the plurality of bits in which a second sub-ECC circuit is error-correctable; and
controlling an output multiplexer circuit to output at least one of the first error bits to the second sub-ECC circuit based on the number of the first error bits exceeding a first number and the number of the second error bits being less than the first number.

12. The method of claim 11, further comprising:
determining a first bit among the first plurality of bits as a first error bit, the first bit having a data value different from a bit having a corresponding address value among the plurality of input bits; and
determining a second bit among the second plurality of bits as a second error bit, the second bit having a data value different from a bit having a corresponding address value among the plurality of input bits.

13. The method of claim 11, further comprising:
in response to the number of the first error bits exceeding the first number and the number of the second error bits being less than a second number,
outputting a 1-1 bit of the first plurality of bits to the second sub-ECC circuit through a first output multiplexer in the output multiplexer circuit, and
outputting a 2-1 bit of the second plurality of bits to the first sub-ECC circuit through a second output multiplexer in the output multiplexer circuit.

14. The method of claim 13, further comprising:
in response to first output bits output from the first sub-ECC circuit and second output bits output from the second sub-ECC circuit having a same value as each of the plurality of input bits having corresponding address values,
storing selection information about a selection signal generated to control the output multiplexer circuit in the memory device; and
storing address information of the first error bits and the second error bits.

15. The method of claim 14, further comprising:
in response to receiving an operation request for the memory device, loading first selection information from the memory device, wherein the first selection information is stored in correspondence with first address information corresponding to an address value included in the operation request; and
controlling the output multiplexer circuit based on the first selection information.

16. A memory system comprising:
a memory device configured to read a plurality of bits; and
a memory controller configured to control an operation of the memory device, and
wherein the memory controller comprises an ECC circuit, the ECC circuit comprises:
a first sub-ECC circuit configured to correct a first error comprising first error bits, and
a second sub-ECC circuit configured to correct a second error comprising second error bits, and
wherein the memory device comprises:
an output multiplexer circuit configured to output the plurality of bits, wherein a first plurality of bits among the plurality of bits is output to the first sub-ECC circuit, and wherein a second plurality of bits among the plurality of bits is output to the second sub-ECC circuit; and
a control logic circuit configured to control the output multiplexer circuit, and
wherein the control logic circuit is further configured to:
control the output multiplexer circuit to output at least some of the first error bits to the second sub-ECC circuit based on a number of the first error bits exceeding a first number and a number of the second error bits being less than the first number.

17. The memory system of claim 16, wherein the output multiplexer circuit further comprises:
a first output multiplexer configured to receive a 1-1 bit and a 2-1 bit to be output to the first sub-ECC circuit; and
a second output multiplexer configured to receive the 1-1 bit and the 2-1 bit to be output to the second sub-ECC circuit, and
wherein, based on the first error bits include the 1-1 bit and the second error bits not including the 2-1 bit, and in response to the number of first error bits exceeding the first number and the number of second error bits being less than the first number, the control logic circuit is further configured to:
output the 2-1 bit to the first sub-ECC circuit through the first output multiplexer; and
output the 1-1 bit to the second sub-ECC circuit through the second output multiplexer.

18. The memory system of claim 16, wherein, based on a value of each bit output from the first sub-ECC circuit and the second sub-ECC circuit corresponding to a value of each bit input to the memory device, the control logic circuit is further configured to:
store selection information about a selection signal transmitted to the output multiplexer circuit in an one time programmable (OTP) block.

19. The memory system of claim 18, wherein, based on a sum of the number of first error bits and the number of second error bits being less than or equal to a second number, the second number being twice the first number, the control logic circuit is further configured to:
store address information of the first error bits and the second error bits in the OTP block in correspondence with the selection information.

20. The memory system of claim 19, wherein the control logic circuit is further configured to:
obtain the address information and the selection information stored in the OTP block through a register in response to the memory device being driven;
in response to that an operation request for the memory device being received, load first selection information stored in correspondence with first address information corresponding to an address value included in the operation request from the register, the first address information being among the address information; and
control the output multiplexer circuit based on the first selection information.
